(19) United States
(12) Patent Application Publication
(10) Pub. No.: US 2022/0359794 A1
(43) Pub. Date: Nov. 10, 2022

(54) LIGHT-EMITTING DIODE STRUCTURE

(71) Applicant: Lextar Electronics Corporation, Hsinchu (TW)

(72) Inventors: Te-Chung WANG, Hsinchu (TW); Ya-Huei YANG, Hsinchu (TW)

(21) Appl. No.: 17/659,662

(22) Filed: Apr. 19, 2022

(30) Foreign Application Priority Data
May 8, 2021 (CN) 202110498691.2

(51) Int. Cl. H01L 33/46

(52) U.S. Cl. CPC H01L 33/46; H01L 33/382

(57) ABSTRACT

A light-emitting diode structure includes a light-emitting part and a reflective part. The light-emitting part has a light-emitting surface. The reflective part is on the light-emitting part opposite to the light-emitting surface. The reflective part is a gradient distributed Bragg reflection structure and includes a plurality of first dielectric layers and a plurality of second dielectric layers. The second dielectric layers have a refractive index different from that of the first dielectric layer, and are alternately stacked with the first dielectric layers. Each of the first dielectric layers has a different optical thickness, and each of the second dielectric layers has a different optical thickness. The optical thicknesses of the first dielectric layers and the second dielectric layers vary in a gradient way away from the light-emitting part.

### CROSS-REFERENCE TO RELATED APPLICATION

This application claims priority to China Application Serial Number 202110498691.2, filed May 8, 2021, which is herein incorporated by reference.

### BACKGROUND

### Technical Field

The present disclosure relates to a light-emitting diode structure.

### Description of Related Art

The statements in this section merely provide background information related to the present disclosure and do not necessarily constitute prior art.

Nowadays, various light-emitting diode (LED) packaging components have been widely used in the fields of backlight modules and general lighting, and many of them are mixed with multiple colors. The effectiveness of such LED packaging components depends on the luminous efficiency of the LED constituent materials and the light extraction rate of the external structure, and related research is very important in this field.

In the past ten years, in order to improve the light extraction rate, a rough surface can be formed on the light-emitting plane of the LED chip, the shape of the overall structure of the LED package can be adjusted, and highly reflective materials (such as aluminum) can also be used as the metal reflective structure. However, because metals are more susceptible to oxidation and the reflectance decreases over time, the more recent research direction has gradually turned to distributed Bragg reflector (DBR). Generally, DBR is formed by alternately stacking materials with different refractive indexes. The different materials in the stacked layer have different fixed thicknesses. The thickness is defined by a single and specific target light wavelength range. Based on the principle of constructive interference and destructive interference caused by beam phase difference, the light extraction rate is improved.

### SUMMARY

A DBR structure solves the problem of reduced reflectance due to quality degradation, and can achieve high reflectance in a narrow wavelength range (for example, the wavelength of light of a specific color). However, when the required wavelength range is widened, the reflectance will drop significantly. In addition, although the DBR structure can exhibit high reflectance for incident light compared to that parallel to the normal line of the plane, the reflectance will also be significantly reduced when the incident angle is increased. In this regard, some studies divide the DBR structure into different thickness regions, that is, make it include multiple groups of DBRs with different target light wavelength ranges. The laminated layers of the same material in each DBR still have the same thickness, but still cannot meet the needs of expanding the wavelength range, and obvious destructive interference often occurs.

According to an embodiment of the disclosure, a light-emitting diode structure includes a light-emitting part and a reflective part. The light-emitting part has a light-emitting surface. The reflective part is on a side of the light-emitting part opposite to the light-emitting surface. The reflective part is a gradient distributed Bragg reflection structure and includes a plurality of first dielectric layers and a plurality of second dielectric layers. The second dielectric layers are alternately stacked with the first dielectric layers and have a refractive index different from a refractive index of the first dielectric layers. Each of the first dielectric layers has a different optical thickness. Each of the second dielectric layers has a different optical thickness. The optical thicknesses of the first dielectric layers and the optical thicknesses of the second dielectric layers vary in a gradient way away from the light-emitting part.

In an embodiment of the disclosure, a difference between the optical thicknesses of any adjacent and contacting two of the first dielectric layers and the second dielectric layers is between 1% and 3%.

In an embodiment of the disclosure, the light-emitting diode structure further includes a flat layer and a protective layer. The flat layer is located between the light-emitting part and the reflective part and attached to the reflective part. The flat layer includes a dielectric material. The protective layer is attached to the reflective part. The reflective part is located between the flat layer and the protective layer. The protective layer includes a dielectric material.

In an embodiment of the disclosure, an actual thickness of the flat layer is between 4(λₘₐₓ/4n_{f}) and 8(λₘₐₓ/4n_{f}). An actual thickness of the protective layer is between 1(λₘₐₓ/4nₚ) and 2(λₘₐₓ/4nₚ). λₘₐₓ is a maximum wavelength value of a selected wavelength range. n_{f} and nₚ are refractive indices of the flat layer and the protective layer, respectively.

In an embodiment of the disclosure, for incident light with a wavelength of 1000 nm to 1100 nm and incident toward the light-emitting part from a side of the protective layer, a reflectance of the reflective part is less than 15%.

In an embodiment of the disclosure, for incident light that is incident from the light-emitting part toward the protective layer and parallel to a normal direction of an interface between the reflective part and the flat layer, a reflectance of the reflective part is greater than 95%. For incident light that is incident from the light-emitting part toward the protective layer and forms an angle of 60° with the normal direction of the interface between the reflective part and the flat layer, a reflectance of the reflective part is greater than 40%.

In an embodiment of the disclosure, the light-emitting diode structure further includes a substrate located between the light-emitting part and the flat layer and attached to the flat layer.

In an embodiment of the disclosure, the selected wavelength range is 450 nm to 670 nm.

In an embodiment of the disclosure, an actual thickness of any one of the first dielectric layers is greater than actual thicknesses of two of the second dielectric layers respectively adjacent to opposite sides of said any one of the first dielectric layers. The actual thickness of any one of the second dielectric layers is smaller than the actual thicknesses of two of the first dielectric layers respectively adjacent to opposite sides of said any one of the second dielectric layers.

In an embodiment of the disclosure, actual thicknesses of the first dielectric layers are between 70 nm and 140 nm. Actual thicknesses of the second dielectric layers are between 35 nm and 70 nm.

In an embodiment of the disclosure, an actual thickness of the flat layer is between 400 nm and 1000 nm. An actual thickness of the protective layer is between 180 nm and 360 nm.

In an embodiment of the disclosure, the light-emitting diode structure further includes a substrate. The light-emitting part is located between the substrate and the reflective part.

In an embodiment of the disclosure, the light-emitting diode structure further includes a substrate. The reflective part is located between the substrate and the light-emitting part.

In an embodiment of the disclosure, the optical thicknesses of the first dielectric layers and the second dielectric layers that are stacked alternately vary in a gradient way away from the light-emitting part.

In the present disclosure, the effect of broadband and high reflectance can be achieved by disposing the reflective part with gradient optical thicknesses.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a cross-sectional view of a light-emitting diode structure according to some embodiments of the present disclosure;

FIG. 2A is a graph of wavelength-reflectance curves of light incident on a reflective part in a normal direction in some embodiments of the present disclosure;

FIG. 2B is a graph of wavelength-reflectance curves of light incident on the reflective part at an incident angle of 60° in some embodiments of the present disclosure;

FIG. 3A is a graph of wavelength-reflectance curves of light incident on a reflective part in a normal direction without using a flat layer and a protective layer in some embodiments of the present disclosure;

FIG. 3B is a graph of wavelength-reflectance curves of light incident on a reflective part in the normal direction using a flat layer and a protective layer with specific thicknesses in some embodiments of the present disclosure;

FIG. 4 is a cross-sectional view of a light-emitting diode structure according to some embodiments of the present disclosure;

FIG. 5 is a cross-sectional view of a light-emitting diode structure according to some embodiments of the present disclosure;

FIG. 6 is a cross-sectional view of a light-emitting diode structure according to some embodiments of the present disclosure; and

FIG. 7 is a cross-sectional view of a light-emitting diode structure according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts. However, specific structural and functional details disclosed herein are merely representative for purposes of describing example embodiments, and thus may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the disclosure.

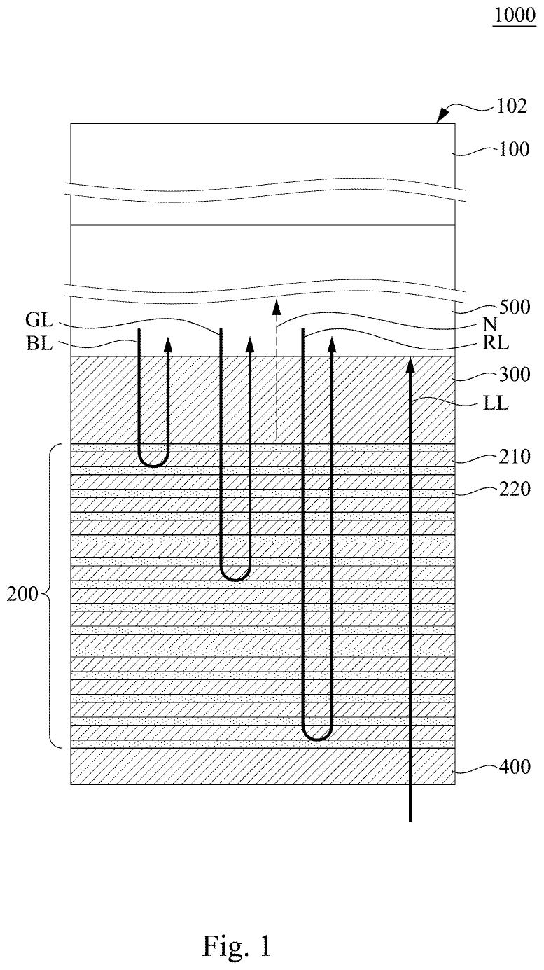

Reference is made to FIG. 1. FIG. 1 is a cross-sectional view of a light-emitting diode structure 1000 according to some embodiments of the present disclosure. The light-emitting diode structure 1000 includes a light-emitting part 100 and a reflective part 200. The light-emitting part 100 has a light-emitting surface 102. The reflective part 200 is on a side of the light-emitting part 100 opposite to the light-emitting surface 102. The reflective part 200 includes a plurality of first dielectric layers 210 and a plurality of second dielectric layers 220. The second dielectric layers 220 have a refractive index different from that of the first dielectric layers 210 and are alternately stacked with the first dielectric layers 210. In detail, the first dielectric layers 210 may be made of the same material, such as silicon dioxide (SiO₂). The second dielectric layers 220 may be made of the same material, such as titanium dioxide (TiO₂) or trititanium pentoxide (Ti₃O₅) when the quality of titanium oxide is better. The aforementioned materials are not used to limit the scope of this disclosure. The first dielectric layers 210 and the second dielectric layers 220 are two different materials. Except for the two outermost layers of the reflective part 200, opposite sides of each of the first dielectric layers 210 are respectively attached to two of the second dielectric layers 220, and opposite sides of each of the second dielectric layers 220 are respectively attached to two of the first dielectric layers 210. The two outermost layers mentioned above may both be the first dielectric layers 210 or the second dielectric layers 220. In addition, the numbers of the first dielectric layers 210 and the second dielectric layers 220 shown in FIG. 1 are only an example. In some embodiments, the total number of layers of the first dielectric layers 210 and the second dielectric layers 220 is about 28.

Each of the first dielectric layers 210 has a different optical thickness, and each of the second dielectric layers 220 has a different optical thickness. The optical thickness refers to the product of the actual thickness and the refractive index of the medium (i.e., the dielectric layer). The actual thickness can be understood as the physical thickness that can be measured by using the software ruler function on the screen after taking a photo with a microscope. That is, the actual thickness is the generally recognized thickness. The optical thicknesses of the first dielectric layers 210 and the optical thicknesses of the second dielectric layers 220 vary in a gradient way away from the light-emitting part 100. The “vary in a gradient way” refers to gradual increase or decrease of the optical thickness along the stacking direction without repetitive optical thickness. In other words, the reflective part 200 can be understood as a Bragg reflection structure with gradient distributed optical thicknesses. Different thicknesses can be designed to correspond to different light wavelengths, and through thickness matching, a relatively wide wavelength band (for example, visible light band) incident from the light-emitting part 100 to the reflective part 200 can achieve good reflectivity, which solves the defect that most of the known distributed Bragg reflector (DBR) structures only have high reflectance for specific narrow bands. Some aspects of the “vary in a gradient way” are explained in more detail below.

In some embodiments, if the number of the first dielectric layers 210 is m (m is a positive integer), the actual thickness of the x-th layer (x is a positive integer and 1<x<m) is set to λₓ/4n₁, and the optical thickness is λₓ/4. n₁ is the refractive index of the first dielectric layers 210, λₓ is the selected wavelength range to be corresponded, and each first dielectric layer 210 corresponds to different λₓ. The value of λₓ may gradually increase (or decrease) from the first layer to the m-th layer. In addition, the first layer referred here may be the first dielectric layer 210 closest to the light-emitting part 100, and the m-th layer may be the first dielectric layer 210 farthest from the light-emitting part 100.

Following the previous paragraph, actual values are now used for a more intuitive explanation. The following values are for ease of understanding and are not intended to limit the scope of this disclosure. For example, the reflective part 200 includes ten layers (i.e., m=10) of the first dielectric layers 210. The refractive index of the first dielectric layers 210 is 1.45 (i.e., silicon dioxide, n₁=1.45), and the selected wavelength range for the first dielectric layers 210 is 460 nm to 640 nm. According to the aforementioned values, the actual value of λₓ is 460+(x−1)((640−460)/(10−1)). In other words, for the first dielectric layers 210, λ₁ is 460 nm, λ₂ is 480 nm, λ₃ is 500 nm, and so on, λ₁₀ is 640 nm. It can be further deduced that the actual thickness of the first layer of the first dielectric layers 210 is 79.3 nm (i.e., 460/(4*1.45)), and the optical thickness is 115 nm; the actual thickness of the second layer is 82.7 nm (i.e., 480/(4*1.45)), and the optical thickness is 120 nm; and so on, the actual thickness of the 10th layer is 110.3 nm (i.e., 640/(4*1.45)), and the optical thickness is 160 nm.

Similarly, if the number of the second dielectric layers 220 is p (p is a positive integer), the actual thickness of the y-th layer (y is a positive integer and 1<x<p) is λ_{y}/4n₂, and the optical thickness is λ_{y}/4. n₂ is the refractive index of the second dielectric layers 220, λ_{y} is the selected wavelength range to be corresponded, and each second dielectric layer 220 corresponds to different λ_{y}. The value of λ_{y} may gradually increase (or decrease) from the first layer to the p-th layer. In addition, the first layer referred here may be the second dielectric layer 220 closest to the light-emitting part 100, and the p-th layer may be the second dielectric layer 220 farthest from the light-emitting part 100.

Following the previous paragraph, actual values are now used for a more intuitive explanation. For example, the reflective part 200 includes eleven layers (i.e., p=11) of the second dielectric layers 220. The refractive index of the second dielectric layers 220 is 2.5 (i.e., trititanium pentoxide, n₂=2.5), and the selected wavelength range for the second dielectric layers 220 is 450 nm to 650 nm. According to the aforementioned values, the actual value of λ_{y} is 450+(y−1)((650−450)/(11−1)). In other words, for the second dielectric layers 220, λ₁ is 450 nm, λ₂ is 470 nm, λ₃ is 490 nm, and so on, λ₁₁ is 650 nm. It can be further deduced that the actual thickness of the first layer of the second dielectric layers 220 is 45 nm (i.e., 450/(4*2.5)), and the optical thickness is 112.5 nm; the actual thickness of the second layer is 47 nm (i.e., 470/(4*2.5)), and the optical thickness is 117.5 nm; and so on, the actual thickness of the 11th layer is 65 nm (i.e., 650/(4*2.5)), and the optical thickness is 162.5 nm.

The first dielectric layers 210 and the second dielectric layers 220 above-mentioned can be combined to form a series of dielectric layer thicknesses in the selected wavelength range of 450 nm to 650 nm after being alternately stacked, and the thicknesses of these dielectric layers can meet the conditions and limitations of the above paragraphs. In more detail, after alternately stacking the first dielectric layers 210 and the second dielectric layers 220 using the above actual values, a structure with optical thicknesses varying in a gradient way can be formed. The optical thicknesses sequentially are 112.5 nm (a second dielectric layer 220), 115 nm (a first dielectric layer 210), 117.5 nm (a second dielectric layer 220), 120 nm (a first dielectric layer 210), . . . , 160 nm (a first dielectric layer 210), and 162.5 nm (a second dielectric layer 220). The structure has 21 layers (m layers+p layers), which can be used as an aspect of the reflective part 200. In other words, after the first dielectric layers 210 and the second dielectric layers 220 are alternately stacked, the optical thickness of each layer vary gradually from a position adjacent to the light-emitting part 100 along a direction away from the light-emitting part 100. In some embodiments, the second dielectric layer 220 with an optical thickness of 112.5 nm is the closest to the light-emitting part 100, and the second dielectric layer 220 with an optical thickness of 162.5 nm is the farthest from the light-emitting part 100. It should be noted that these limitations are only examples, and are based on the spirit of completing gradient and non-repetitive optical thicknesses, and achieving a broadband and high reflectance effect compared to the prior art.

In some embodiments, the actual thickness of any one of the first dielectric layers 210 is greater than the actual thicknesses of two of the second dielectric layers 220 respectively adjacent to opposite sides of said any one of the first dielectric layers 210. In addition, the actual thickness of any one of the second dielectric layers 220 is smaller than the actual thicknesses of two of the first dielectric layers 210 respectively adjacent to opposite sides of said any one of the second dielectric layers 220. In some embodiments, the actual thickness of a single first dielectric layer 210 is between 70 nm and 140 nm, and the actual thickness of a single second dielectric layer 220 is between 35 nm and 70 nm.

Reference is made to FIG. 1. If the optical thickness and the corresponding wavelength (λₓ and λ_{y}) are gradually increased in the direction away from the light-emitting part 100, as shown in the figure, the blue light BL will be reflected first, the green light GL will then be reflected, and the long-wavelength red light RL will be reflected at the place of the reflective part 200 farthest away from the substrate 500.

In some embodiments, the light-emitting diode structure 1000 further includes a flat layer 300 and a protective layer 400. The flat layer 300 includes a dielectric material, is located between the light-emitting part 100 and the reflective part 200, and is attached to the reflective part 200. In some embodiments, the composition material of the flat layer 300 is the same as the composition material of the first dielectric layers 210 (for example, silicon dioxide), but the disclosure is not limited thereto. The protective layer 400 includes a dielectric material and is attached to the reflective part 200. The reflective part 200 is located between the flat layer 300 and the protective layer 400. In some embodiments, the composition material of the protective layer 400 is the same as the composition material of the first dielectric layers 210 (for example, silicon dioxide), but the disclosure is not limited thereto. In some embodiments, the flat layer 300 and the protective layer 400 are made of the same material.

In some embodiments, the light-emitting diode structure 1000 includes a substrate 500. The substrate 500 is located between the light-emitting part 100 and the flat layer 300 and attached to the flat layer 300. The substrate 500 may be a growth substrate for growing the light-emitting part 100, but the disclosure is not limited thereto. Since the surface of the substrate 500 is cut and polished, the surface roughness is relatively large. If the first dielectric layer 210 or the second dielectric layer 220 of only about 100 nm are directly formed on the rough surface, the accuracy of the thicknesses will be excessively affected by the high surface roughness of the substrate 500, so that the first dielectric layer 210 and the second dielectric layer 220 lose their original function of adjusting the optical phase difference. Therefore, by first forming the flat layer 300, the light can have a consistent light phase difference response when entering the reflective part 200. In addition to the effect equivalent to the reflective part 200 reflecting the light from the light-emitting part 100, the protective layer 400 also has the effect of helping the laser light LL for cutting incident from the protective layer 400 to the light-emitting diode structure 1000 to pass through the reflective part 200 smoothly, which will be described in detail later.

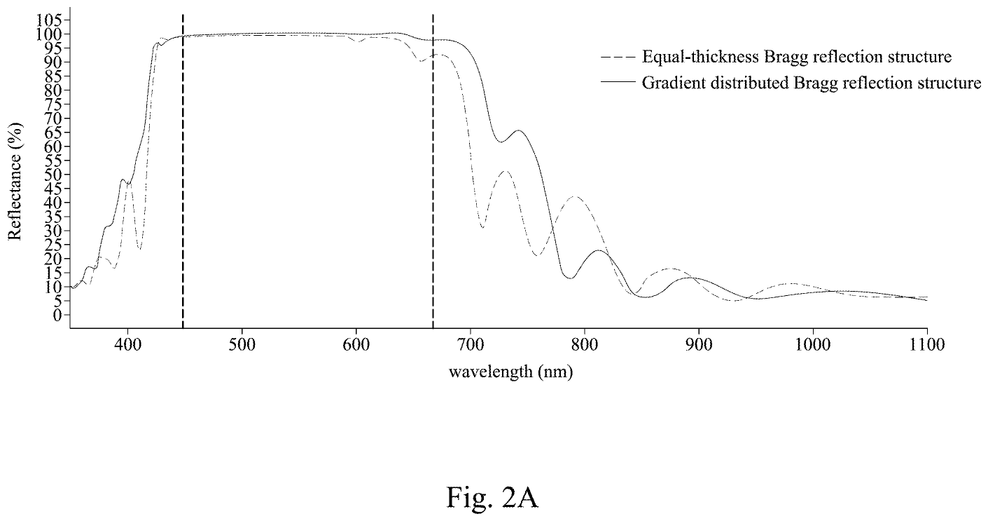

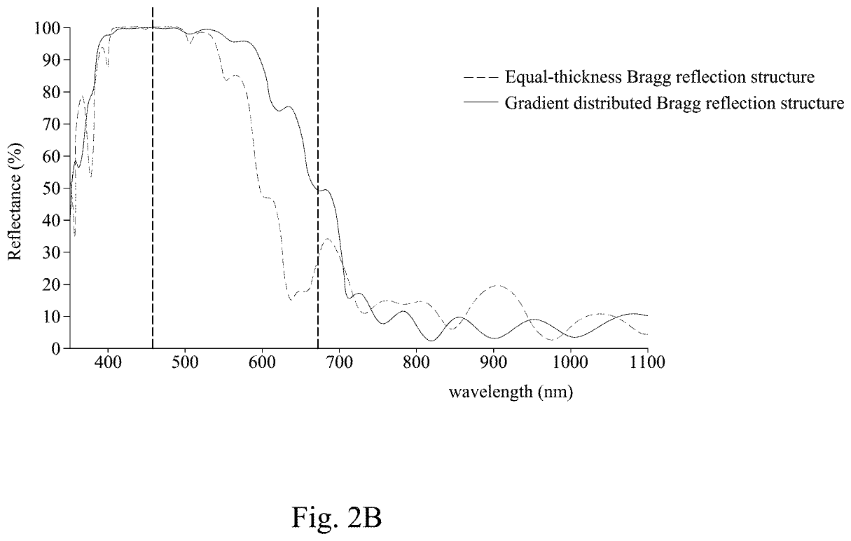

The data results of a specific embodiment designed according to the above principles will be explained as follows. Reference is made to FIGS. 2A and 2B. FIG. 2A is a graph of wavelength-reflectance curves of light incident on the reflective part 200 in a normal direction N in some embodiments of the present disclosure. FIG. 2B is a graph of wavelength-reflectance curves of light incident on the reflective part 200 at an incident angle of 60° in some embodiments of the present disclosure. The real structural connotation of equal-thickness Bragg reflection structure represented by the dotted lines in the above two figures are briefly described here.

The data of the above-mentioned equal-thickness Bragg reflection structure is taken from a structure where the first dielectric layers 210 are made of silicon dioxide and the second dielectric layers 220 are made of trititanium pentoxide. The “equal-thickness” means that in the lamination in the reflective part 200 (for example, thirteen silicon dioxide layers and fourteen trititanium pentoxide layers), the actual thicknesses of the silicon dioxide layers are substantially the same, and the actual thicknesses of the trititanium pentoxide layers are substantially the same. The actual thickness of the silicon dioxide layers is different from the actual thickness of the trititanium pentoxide layers. In the example of the equal-thickness Bragg reflection structure as the control group, the actual thickness of the silicon dioxide layers is, for example, 90 nm, and the actual thickness of the trititanium pentoxide layers is, for example, 50 nm.

Next, the solid lines in FIG. 2A and FIG. 2B represent the reflective part 200 composed of a gradient distributed Bragg reflection structure. Obviously, for the incident light from the light-emitting part 100 to the protective layer 400 and parallel to the normal direction N of the interface between the reflective part 200 and the flat layer 300, the gradient distributed structure makes the reflective part 200 have a reflectance of more than 95% for the incident light with a wavelength ranging from 450 nm to 670 nm, even extending to 700 nm. In addition, for the incident light from the light-emitting part 100 toward the protective layer 400 and forms an angle of 60° with the normal direction N of the interface between the reflective part 200 and the flat layer 300, the reflectance of the reflective part 200 for the incident light with a wavelength in the range of 450 nm to 670 nm is greater than 40%, and even as high as 50% for the incident light with a wavelength of 670 nm. From the comparison data shown in FIG. 2A and FIG. 2B, it can be seen that in the common visible light band (for example, the wavelength range of 450 nm to 670 nm), the gradient distributed Bragg reflection structure adopted by the reflective part 200 in the embodiment presents better reflectance data than the existing equal-thickness Bragg reflection structure. Even in the long wavelength band approaching 700 nm, the degree of reflectance reduction of the gradient distributed Bragg reflection structure is smaller than that of the aforementioned equal-thickness Bragg reflection structure. The data shows that the reflective part 200 in the embodiment of the present disclosure can make the light-emitting diode structure 1000 exhibit a higher light extraction rate for the light-emitting part 100 than in the prior art.

The following several embodiments are provided in order to fine-tune the light extraction rate of the light-emitting diode structure 1000 to a better and stable state. In some embodiments, a difference between the optical thicknesses of any adjacent and contacting two of the first dielectric layers 210 and the second dielectric layers 220 is between 1% and 3%. It is worth noting that when the difference between the optical thicknesses of any adjacent two dielectric layers is greater than 3%, the reflectance will be poor due to too few stacked layers (for example, less than eighteen layers) in the fixed selected wavelength range (the highest reflectance is reduced to less than 98%). As a result, the overall efficiency is not as good as the existing metal mirrors. On the contrary, when the difference between the optical thicknesses of any adjacent two dielectric layers is less than 1%, although the reflectance can be maintained above 99%, there are too many stacked layers (probably more than forty layers) in the fixed wavelength range, other problems such as poor production efficiency and poor thermal conductivity will arise.

In some embodiments, if n_{f} and nₚ respectively represent the refractive indices of the flat layer 300 and the protective layer 400, the actual thickness of the flat layer 300 is between 4(λₘₐₓ/4n_{f}) and 8(λₘₐₓ/4n_{f}), and the actual thickness of the protective layer 400 is between 1(λₘₐₓ/4nₚ) and 2(λₘₐₓ/4nₚ). In some embodiments, n_{f}=nₚ=1.45, that is, the flat layer 300 and the protective layer 400 are both silicon dioxide layers. λₘₐₓ is the maximum wavelength of the selected wavelength range. The selected wavelength range may be the main wavelength range emitted by the light-emitting part 100, but the disclosure is not limited thereto. In some embodiments, the selected wavelength range is from 450 nm to 670 nm for common visible light. At this time, λₘₐₓ can be set to 670 nm. The parameter setting method illustrated in this paragraph can further optimize the aforementioned effects of the flat layer 300 and the protective layer 400.

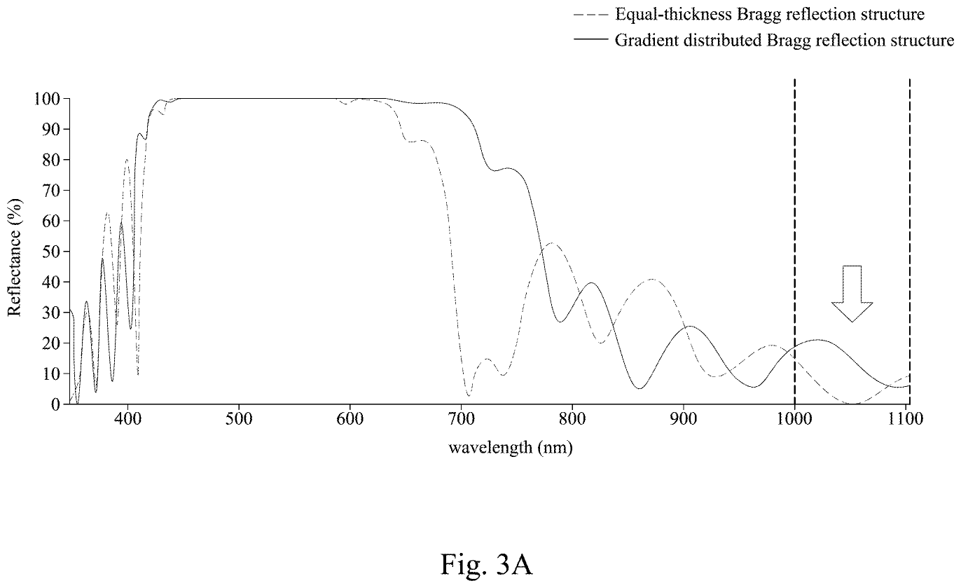

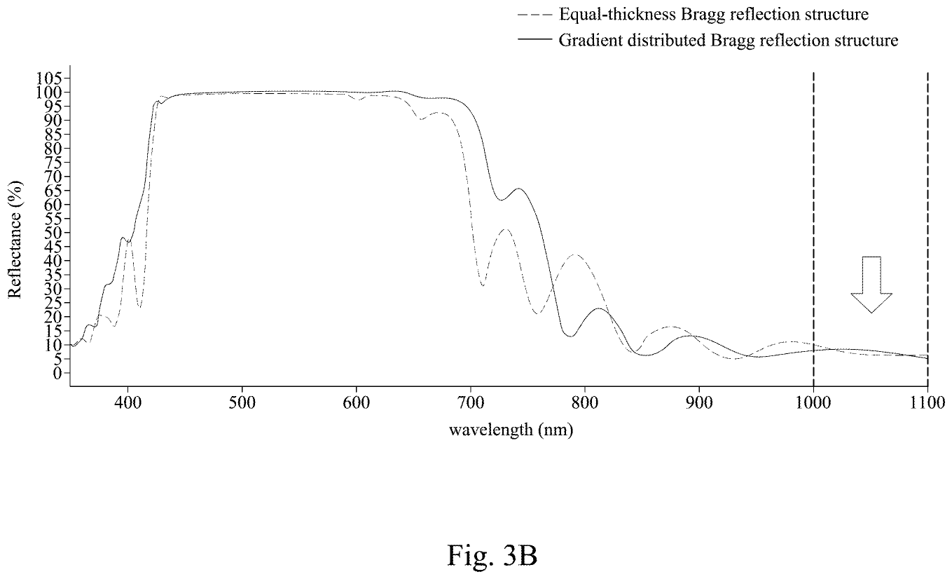

In some embodiments, the actual thickness of the flat layer 300 is 5(λₘₐₓ/4n_{f}), and the actual thickness of the protective layer 400 is 2(λₘₐₓ/4nₚ). At this time, reference can be made to FIG. 3A and FIG. 3B to illustrate the effect of the actual thickness. FIG. 3A is a graph of wavelength-reflectance curves of light incident on the reflective part 200 in the normal direction N without using the flat layer 300 and the protective layer 400 in some embodiments of the present disclosure. FIG. 3B is a graph of wavelength-reflectance curves of light incident on the reflective part 200 in the normal direction N using the flat layer 300 and the protective layer 400 with specific thicknesses in some embodiments of the present disclosure. Obviously, as shown in FIG. 3A, the reflectance fluctuates in the infrared light range corresponding to wavelengths of about 1000 nm to 1100 nm, and the fluctuation is even greater than 20% in the region near 1000 nm. This will cause difficulties when cutting with the laser light LL. The wavelength of the laser light LL may be 1064 nm, but the disclosure is not limited thereto. In some embodiments, the actual thickness of the flat layer is between 400 nm and 1000 nm, and the actual thickness of the protective layer is between 180 nm and 360 nm. In some embodiments, the actual thickness of the flat layer 300 is close to 600 nm, for example, 580 nm. In some embodiments, the actual thickness of the protective layer 400 is 230 nm.

In addition, in order to facilitate the laser cutting operation of the light-emitting diode structure 1000, for incident light with a wavelength of 1000 nm to 1100 nm and incident from a side of the protective layer 400 toward the light-emitting part 100, the reflectance of the reflective part 200 is controlled to be less than 15%, which can be achieved at least by the structural conditions that the actual thickness of the flat layer 300 is 5(λₘₐₓ/4n_{f}) and the actual thickness of the protective layer 400 is 2(λₘₐₓ/4nₚ). In this way, while increasing the reflectance of the reflective part 200 to the incident light from the light-emitting part 100, the laser cutting process with a long wavelength can also be allowed to achieve the dual effects of high light extraction rate and convenient laser cutting processing.

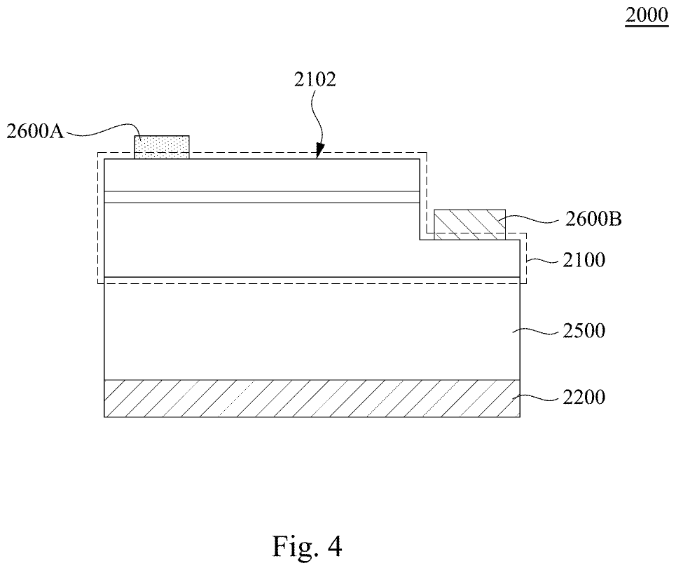

Reference is made to FIG. 4. FIG. 4 is a cross-sectional view of a light-emitting diode structure 2000 according to some embodiments of the present disclosure, in which the light-emitting part 2100 is a light-emitting diode with a lateral structure. In such an embodiment, the substrate 2500 is located between the light-emitting part 2100 and the reflective part 2200, and the light-emitting surface 2102 is located on the side of the light-emitting part 2100 opposite to the substrate 2500. The electrode 2600A (for example, a positive electrode) and the electrode 2600B (for example, a negative electrode) are located on the same side of the light-emitting diode structure 2000 as the light-emitting surface 2102.

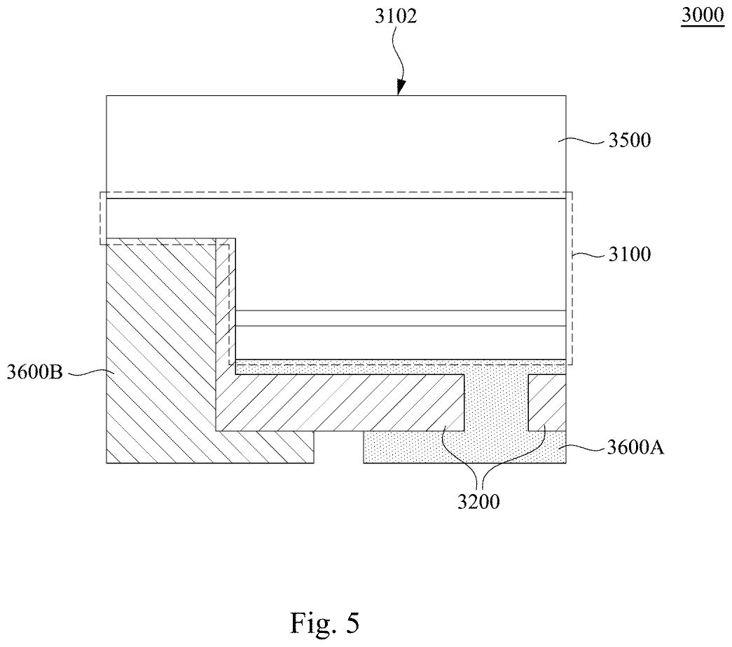

Reference is made to FIG. 5. FIG. 5 is a cross-sectional view of a light-emitting diode structure 3000 according to some embodiments of the present disclosure, in which the light-emitting part 3100 is a light-emitting diode with a flip chip structure. In such an embodiment, the light-emitting part 3100 is located between the substrate 3500 and the reflective part 3200, and the light-emitting surface 3102 is located on the side of the substrate 3500 opposite to the light-emitting part 3100. The electrode 3600A (for example, a positive electrode) and the electrode 3600B (for example, a negative electrode) are located on the side of the light-emitting part 3100 opposite to the substrate 3500. In some embodiments, the reflective part 3200 is covered by the electrode 3600A and the electrode 3600B.

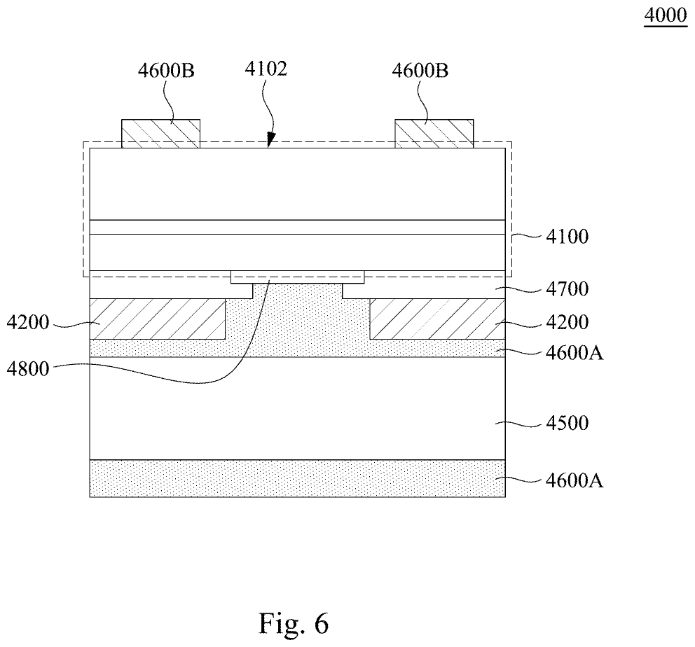

Reference is made to FIG. 6. FIG. 6 is a cross-sectional view of a light-emitting diode structure 4000 according to some embodiments of the present disclosure, in which the light-emitting part 2100 is a light-emitting diode with a vertical structure. In such an embodiment, the reflective part 4200 is located between the substrate 4500 and the light-emitting part 4100, and the light-emitting surface 4102 is located on the side of the light-emitting part 4100 opposite to the substrate 4500. The electrode 4600A (for example, a positive electrode) is located on the substrate 4500 of the light-emitting diode structure 4000 opposite to the light-emitting surface 4102, and the electrode 4600B (for example, a negative electrode) is located on the light-emitting part 4100 on the same side as the light-emitting surface 4102. In some embodiments, the light-emitting diode structure 4000 includes a light-transmitting insulating layer 4700 which is in contact with and located between the light-emitting part 4100 and the reflective part 4200. The light-transmitting insulating layer 4700 can allow light to be transmitted to the reflective part 4200. In some embodiments, the light-emitting diode structure 4000 includes a conductive layer 4800 located in the light-transmitting insulating layer 4700 and contacting the light-emitting part 4100 and the electrode 4600A to provide the effect of ohmic contact.

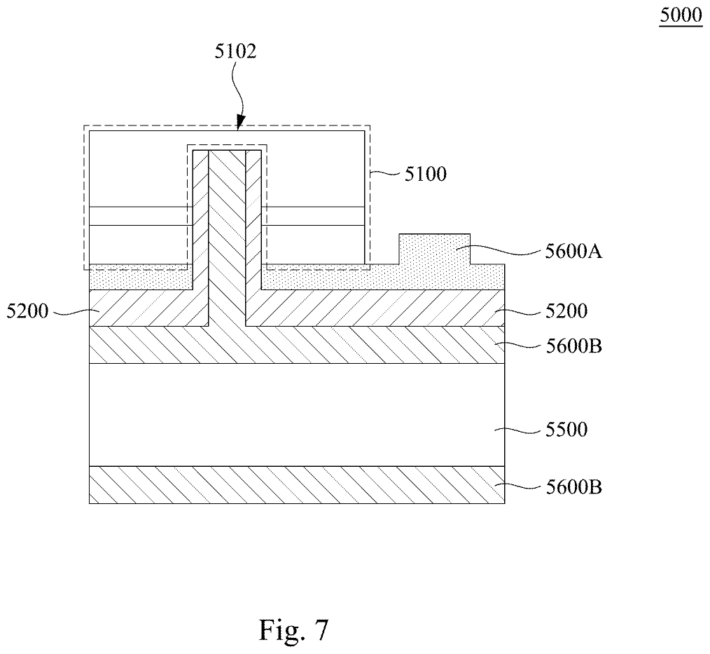

Reference is made to FIG. 7. FIG. 7 is a cross-sectional view of a light-emitting diode structure 5000 according to some embodiments of the present disclosure, in which the light-emitting part 5100 is a light-emitting diode with a vertical flip chip structure. In such an embodiment, the reflective part 5200 is located between the substrate 5500 and the light-emitting part 5100. A part of the reflective part 5200 and a part of the electrode 5600B (for example, a negative electrode) extend into the light-emitting part 5100 and contact the semiconductor layer on the side of the light-emitting surface 5102. Another part of the electrode 5600B is located on the side of the light-emitting diode structure 5000 opposite to the light-emitting surface 5102. The electrode 5600A (for example, a positive electrode) is located between the reflective part 5200 and the light-emitting part 5100, and a part of the electrode 5600A is exposed from the light-emitting diode structure 5000 and faces the same direction as the light-emitting surface 5102.

In summary, the embodiments of the present disclosure provide light-emitting diode structures with gradient distributed Bragg reflection structures. The optical thicknesses of the dielectric layers in the reflection structures vary in a gradient way in one direction, and there are no repetitive optical thicknesses among each other. In this way, the effect of broadband and high reflectance can be achieved. In addition, the arrangement of the flat layer and the protective layer not only can better control the light phase, but also make the reflectance to the infrared laser light low and stable. Therefore, the structure of the light-emitting diode structure can have dual effects such as high light extraction rate and easy cutting processing.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A light-emitting diode structure, comprising:
a light-emitting part having a light-emitting surface; and
a reflective part on a side of the light-emitting part opposite to the light-emitting surface, the reflective part being a gradient distributed Bragg reflection structure and comprising:
a plurality of first dielectric layers; and
a plurality of second dielectric layers alternately stacked with the first dielectric layers and having a refractive index different from a refractive index of the first dielectric layers, wherein each of the first dielectric layers has a different optical thickness, each of the second dielectric layers has a different optical thickness, and the optical thicknesses of the first dielectric layers and the optical thicknesses of the second dielectric layers vary in a gradient way away from the light-emitting part.

2. The light-emitting diode structure of claim 1, wherein a difference between the optical thicknesses of any adjacent and contacting two of the first dielectric layers and the second dielectric layers is between 1% and 3%.

3. The light-emitting diode structure of claim 1, further comprising:
a flat layer located between the light-emitting part and the reflective part and attached to the reflective part, wherein the flat layer comprises a dielectric material; and
a protective layer attached to the reflective part, the reflective part being located between the flat layer and the protective layer, wherein the protective layer comprises a dielectric material.

4. The light-emitting diode structure of claim 3, wherein an actual thickness of the flat layer is between 4(λₘₐₓ/4n_{f}) and 8(λₘₐₓ/4n_{f}), an actual thickness of the protective layer is between 1(λₘₐₓ/4nₚ) and 2(λₘₐₓ/4nₚ), wherein λₘₐₓ is a maximum wavelength value of a selected wavelength range, and n_{f} and nₚ are refractive indices of the flat layer and the protective layer, respectively.

5. The light-emitting diode structure of claim 3, wherein for incident light with a wavelength of 1000 nm to 1100 nm and incident toward the light-emitting part from a side of the protective layer, a reflectance of the reflective part is less than 15%.

6. The light-emitting diode structure of claim 3, wherein for incident light that is incident from the light-emitting part toward the protective layer and parallel to a normal direction of an interface between the reflective part and the flat layer, a reflectance of the reflective part is greater than 95%, and for incident light that is incident from the light-emitting part toward the protective layer and forms an angle of 60° with the normal direction of the interface between the reflective part and the flat layer, a reflectance of the reflective part is greater than 40%.

7. The light-emitting diode structure of claim 3, further comprising a substrate located between the light-emitting part and the flat layer and attached to the flat layer.

8. The light-emitting diode structure of claim 4, wherein the selected wavelength range is 450 nm to 670 nm.

9. The light-emitting diode structure of claim 1, wherein an actual thickness of any one of the first dielectric layers is greater than actual thicknesses of two of the second dielectric layers respectively adjacent to opposite sides of said any one of the first dielectric layers, and the actual thickness of any one of the second dielectric layers is smaller than the actual thicknesses of two of the first dielectric layers respectively adjacent to opposite sides of said any one of the second dielectric layers.

10. The light-emitting diode structure of claim 1, wherein actual thicknesses of the first dielectric layers are between 70 nm and 140 nm, and actual thicknesses of the second dielectric layers are between 35 nm and 70 nm.

11. The light-emitting diode structure of claim 3, wherein an actual thickness of the flat layer is between 400 nm and 1000 nm, and an actual thickness of the protective layer is between 180 nm and 360 nm.

12. The light-emitting diode structure of claim 1, further comprising a substrate, the light-emitting part being located between the substrate and the reflective part.

13. The light-emitting diode structure of claim 1, further comprising a substrate, the reflective part being located between the substrate and the light-emitting part.

14. The light-emitting diode structure of claim 1, wherein the optical thicknesses of the first dielectric layers and the second dielectric layers that are stacked alternately vary in a gradient way away from the light-emitting part.
